(19) United States
(12) Patent Application Publication
(10) Pub. No.: US 2014/0158981 A1
(43) Pub. Date: Jun. 12, 2014

(54) MULTIPLE QUANTUM WELL FOR ULTRAVIOLET LIGHT EMITTING DIODE AND A PRODUCTION METHOD THEREFOR

(71) Applicants: Byoung-Gu Cho, Seoul (KR); Jae-Sik Min, Seoul (KR); Se-Hun Kwon, Busan (KR)

(72) Inventors: Byoung-Gu Cho, Seoul (KR); Jae-Sik Min, Seoul (KR); Se-Hun Kwon, Busan (KR)

(73) Assignee: CHIP TECHNOLOGY CO., LTD, Yongin-si, Gyeonggi-do (KR)

(21) Appl. No.: 14/232,923

(22) PCT Filed: Jul. 16, 2012
(86) PCT No.: PCT/KR2012/005660

§ 371 Date: Jan. 15, 2014

(30) Foreign Application Priority Data
Jul. 21, 2011 (KR) 10-2011-0072491

(51) Int. Cl. H01L 33/06; H01L 33/00

(52) U.S. Cl. CPC H01L 33/06; H01L 33/0075
USPC 257/13; 438/37

(57) ABSTRACT

A multiple quantum well structure for an ultraviolet light-emitting diode, comprising: an Alₓ₁Ga₁₋ₓ₁N barrier portion comprising an AlN barrier atomic layer and a GaN barrier atomic layer, which are alternately arranged; and an Alₓ₂Ga₁₋ₓ₂N quantum well portion formed on the Alₓ₁Ga₁₋ₓ₁N barrier portion and comprising an AlN well atomic layer and a GaN well atomic layer, which are alternately arranged, wherein the Al composition ratio (x1) of the Alₓ₁Ga₁₋ₓ₂N barrier portion is 0-0.7, the Al composition ratio (x2) of the Alₓ₂Ga₁₋ₓ₂N quantum well portion is 0-0.7, the Al composition ratio (x1) of the Alₓ₁Ga₁₋ₓ₁N barrier portion is greater than the Al composition ratio (x2) of the Alₓ₂Ga₁₋ₓ₂N quantum well portion, and the Alₓ₁Ga₁₋ₓ₁N barrier portion and the Alₓ₂Ga₁₋ₓ₂N quantum well portion are alternately deposited two or more times.

### BACKGROUND OF THE INVENTION

The present invention relates to a multiple quantum well structure for an ultraviolet light-emitting diode and a fabrication method thereof, and more particularly to a multiple quantum well structure for an ultraviolet light-emitting diode and a fabrication method thereof, in which the occurrence of dislocation can be effectively inhibited by alternately forming a high-quality barrier layer and a quantum well layer using atomic layer deposition (ALD) which can deposit layers at low temperature.

In recent years, a GaN-based light-emitting diode (LED) has received attention as the next-generation light-emitting device capable of maximizing energy saving. This GaN-based light-emitting diode emits light in the range from a visible light region to an ultraviolet light region.

In the prior art, a multiple quantum well structure for a light-emitting diode was fabricated by metal organic chemical vapor deposition (MOCVD).

However, in the case in which a light-emitting diode having a multiple quantum well structure was fabricated by metal organic chemical vapor deposition (MOCVD), the multiple quantum well structure was deposited at a temperature of 800° C. or higher, and thus dislocation caused by a difference in the coefficient of thermal expansion was widely generated. In addition, the light-emitting diode having this multiple quantum well structure had a very low light emission efficiency.

### SUMMARY OF THE INVENTION

Accordingly, the present invention has been made in order to solve the problems occurring in the prior art, and it is an object of the present invention to provide a multiple quantum well structure for an ultraviolet light-emitting diode, in which the generation of dislocation can be effectively inhibited by alternately forming a high-quality barrier layer and a quantum well layer using atomic layer deposition (ALD) which can deposit layers at low temperature.

Another object of the present invention is to provide a method for fabricating the above-described multiple quantum well structure for an ultraviolet light-emitting diode, which can easily fabricate the multiple quantum well.

The objects to be achieved by the present invention are not limited to the above-mentioned objects, and other objects of the present invention will be clearly understood by those skilled in the art from the following description.

To achieve the above objects, in accordance with an embodiment of the present invention, there is provided a multiple quantum well structure for an ultraviolet light-emitting diode, comprising: an Alₓ₁Ga₁₋ₓ₁N barrier portion comprising an AlN barrier atomic layer and a GaN barrier atomic layer, which are alternately arranged; and an Alₓ₂Ga₁₋ₓ₂N quantum well portion formed on the Alₓ₁Ga₁₋ₓ₁N barrier portion and comprising an AlN well atomic layer and a GaN well atomic layer, which are alternately arranged, wherein the Al composition ratio (x1) of the Alₓ₁Ga₁₋ₓ₁N barrier portion is 0-0.7, the Al composition ratio (x2) of the Alₓ₂Ga₁₋ₓ₂N quantum well portion is 0-0.7, the Al composition ratio (x1) of the Alₓ₁Ga₁₋ₓ₁N barrier portion is greater than the Al composition ratio (x2) of the Alₓ₂Ga₁₋ₓ₂N quantum well portion, and the Alₓ₁Ga₁₋ₓ₁N barrier portion and the Alₓ₂Ga₁₋ₓ₂N quantum well portion are alternately deposited two or more times.

In accordance with another embodiment of the present invention, there is provided a method for fabricating a multiple quantum well structure for an ultraviolet light-emitting diode, the method comprising the steps of: alternately depositing an AlN barrier atomic layer and a GaN barrier atomic layer to form an Alₓ₁Ga₁₋ₓ₁N barrier portion; and alternately depositing an AlN well atomic layer and a GaN well atomic layer on the Alₓ₁Ga₁₋ₓ₁N barrier portion to form an Alₓ₂Ga₁₋ₓ₂N quantum well portion, wherein the Alₓ₁Ga₁₋ₓ₁N barrier portion and the Alₓ₂Ga₁₋ₓ₂N quantum well portion are formed such that the Al composition ratio (x1) of the Alₓ₁Ga₁₋ₓ₁N barrier portion is 0-0.7, the Al composition ratio (x2) of the Alₓ₂Ga₁₋ₓ₂N quantum well portion is 0-0.7, the Al composition ratio (x1) of the Alₓ₁Ga₁₋ₓ₁N barrier portion is greater than the Al composition ratio (x2) of the Alₓ₂Ga₁₋ₓ₂N quantum well portion, and the Alₓ₁Ga₁₋ₓ₁N barrier portion and the Alₓ₂Ga₁₋ₓ₂N quantum well portion are alternately deposited two or more times.

### BRIEF DESCRIPTION OF THE DRAWINGS

FIG. 1 is a transmission electron micrograph of a multiple quantum well structure comprising an Alₓ₁Ga₁₋ₓ₁N (0<x₁<0.7) barrier portion and an Alₓ₂Ga₁₋ₓ₂N (0≦x₂<0.7, x₂<x₁) quantum well portions, fabricated by a method for fabricating a multiple quantum well structure for an ultraviolet light-emitting diode according to an embodiment of the present invention.

FIG. 2 is a graphic diagram showing the photoluminescence (PL) characteristics of multiple quantum well structures for ultraviolet light-emitting diodes, fabricated by depositing an Al_{0.36}Ga_{0.64}N (3.2 nm thick) barrier portion and a GaN (1.2 nm thick) quantum well portion according to embodiments of the present invention.

FIG. 3 is a graphic diagram showing the photoluminescence (PL) characteristics of multiple quantum well structures for ultraviolet light-emitting diodes, fabricated by alternately depositing an Al_{0.36}Ga_{0.64}N (3.2 nm thick) barrier portion and an AlₓGa₁₋ₓN (1.2 nm thick, 0≦x₂<0.2) quantum well portion six times.

### DETAILED DESCRIPTION OF THE INVENTION

Hereinafter, preferred embodiments of the present invention will be described in detail with reference to the accompanying drawings.

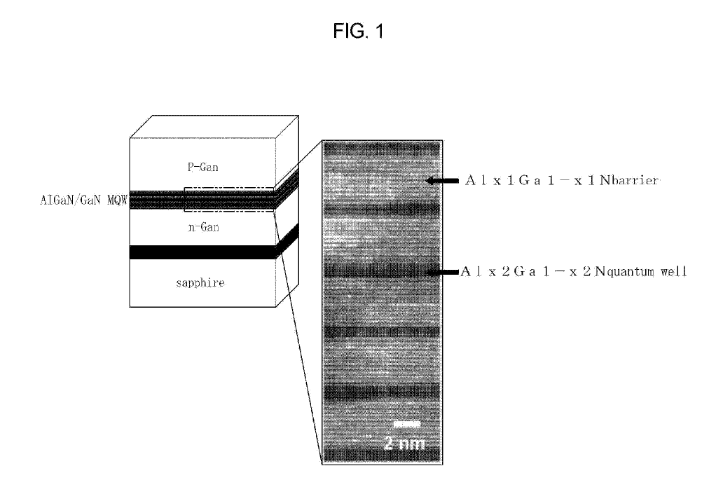

FIG. 1 shows a multiple quantum well structure for an ultraviolet light-emitting diode according to an embodiment of the present invention. As shown in FIG. 1, an AlN barrier atomic layer and a GaN barrier atomic layer are alternately deposited to form an Alₓ₁Ga₁₋ₓ₁N barrier portion.

Then, an AlN well atomic layer and a GaN well atomic layer are alternately deposited on the Alₓ₁Ga₁₋ₓ₁N barrier portion to form an Alₓ₂Ga₁₋ₓ₂N quantum well portion.

Herein, the Alₓ₁Ga₁₋ₓ₁N barrier portion and Alₓ₂Ga₁₋ₓ₂N quantum well portion of the multiple quantum well structure for the ultraviolet light-emitting diode according to the embodiment of the present invention are epitaxially grown on a substrate in the direction of crystal growth by supply of an aluminum source precursor and a gallium source precursor under high pressure at a temperature of 400° C. or lower using atomic layer deposition (ALD).

Meanwhile, the Alₓ₁Ga₁₋ₓ₁N barrier portion and the Alₓ₂Ga₁₋ₓ₂N quantum well portion are formed such that the Al composition ratio (x1) of the Alₓ₁Ga₁₋ₓ₁N barrier portion is 0-0.7, the Al composition ratio (x2) of the Alₓ₂Ga₁₋ₓ₂N quantum well portion is 0-0.7, and the Al composition ratio (x1) of the Alₓ₁Ga₁₋ₓ₁N barrier portion is greater than the Al composition ratio (x2) of the Alₓ₂Ga₁₋ₓ₂N quantum well portion. In addition, the Alₓ₁Ga₁₋ₓ₁N barrier portion and the Alₓ₂Ga₁₋ₓ₂N quantum well portion are alternately deposited two times or more.

If the Al composition ratio (x1) of the Alₓ₁Ga₁₋ₓ₁N barrier portion or the Al composition ratio (x2) of the Alₓ₂Ga₁₋ₓ₂N quantum well portion is greater than 0.7, the mismatch between the AlN material and the GaN material will increase, and thus surface defects can be formed.

Meanwhile, because the Alₓ₁Ga₁₋ₓ₁N barrier portion or the Alₓ₂Ga₁₋ₓ₂N quantum well portion is formed at a temperature of 400° C. using atomic layer deposition (ALD), the dislocation density of each of the portions can be controlled in the range of 10⁴-10⁶ ea/cm².

Moreover, the Alₓ₁Ga₁₋ₓ₁N barrier portion is formed to a thickness of 3-10 nm in order to inhibit the occurrence of direct tunneling. Preferably, the Alₓ₁Ga₁₋ₓ₁N barrier portion is formed to a thickness between 3 nm and 5 nm.

Meanwhile, the Alₓ₂Ga₁₋ₓ₂N quantum well portion is formed to a thickness between 1 nm and 3 nm. If the Alₓ₂Ga₁₋ₓ₂N quantum well portion is formed to a thickness of less than 1 nm, intermixing of the Alₓ₁Ga₁₋ₓ₁N barrier portion can occur, and if the thickness of the Alₓ₂Ga₁₋ₓ₂N quantum well portion is more than 3 nm, the width of the band gap by the quantum effect will decrease, and thus the wavelength of light that is emitted from the multiple quantum well structure can increase. The Alₓ₂Ga₁₋ₓ₂N quantum well portion is preferably formed to have a thickness between 1 nm and 2 nm.

Further, the wavelength of light that is emitted from a multiple quantum well structure for an ultraviolet light-emitting diode according to an embodiment of the present invention can be controlled by controlling the Al composition ratio (x2) of the Alₓ₂Ga₁₋ₓ₂N quantum well portion. Specifically, when the Al composition ratio (x2) of the Alₓ₂Ga₁₋ₓ₂N quantum well portion is 0, light having a wavelength of 360 nm will be emitted, and when the Al composition ratio (x2) of the Alₓ₂Ga₁₋ₓ₂N quantum well portion is 0.7, light having a wavelength of 230 nm will be emitted. In addition, as the thickness of the Alₓ₂Ga₁₋ₓ₂N quantum well portion decreases, the wavelength of light that is emitted from multiple quantum well structure decreases.

The number of Alₓ₁Ga₁₋ₓ₁N barrier portions deposited and the number of Alₓ₂Ga₁₋ₓ₂N quantum well portions deposited are each 2 to 10. If the number of the Alₓ₁Ga₁₋ₓ₁N barrier portions and the Alₓ₂Ga₁₋ₓ₂N quantum well portions increases, the volume of the active layer in the multiple quantum well structure will increase, and thus the light emission efficiency of the multiple quantum well structure will increase. However, the number of the Alₓ₁Ga₁₋ₓN barrier portions and the Alₓ₂Ga₁₋ₓ₂N quantum well portions excessively increases, the flow of electrons and holes between the Alₓ₂Ga₁₋ₓ₂N quantum well portions will be difficult, and thus the light emission efficiency of the multiple quantum well structure can decrease. For this reason, the number of Alₓ₁Ga₁₋ₓ₁N barrier portions deposited and the number of Alₓ₂Ga₁₋ₓ₂N quantum well portions deposited are 10 or less. Preferably, the number of the Alₓ₁Ga₁₋ₓ₁N barrier portions and the number of the Alₓ₂Ga₁₋ₓ₂N quantum well portions are limited to 7 or less in view of the light emission efficiency.

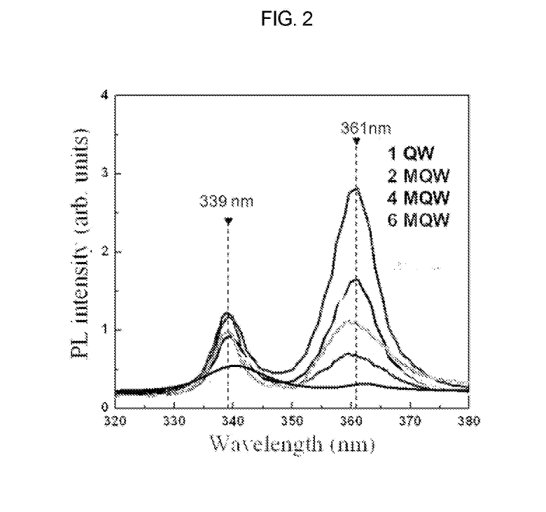

FIG. 2 is a graphic diagram showing the photoluminescence (PL) characteristics of multiple quantum well structures for ultraviolet light-emitting diodes, fabricated by forming an Al_{0.36}Ga_{0.64}N (3.2 nm thick) barrier portion and a GaN (1.2 nm thick) quantum well portion according to embodiments of the present invention.

As shown in FIG. 2, when the number of quantum well portions is 7 or less, the photoluminescence intensity increases as the number of the quantum well portions increases. On the other hand, when the number of quantum well portions is more than 7, the photoluminescence intensity decreases as the number of the quantum well portions increases.

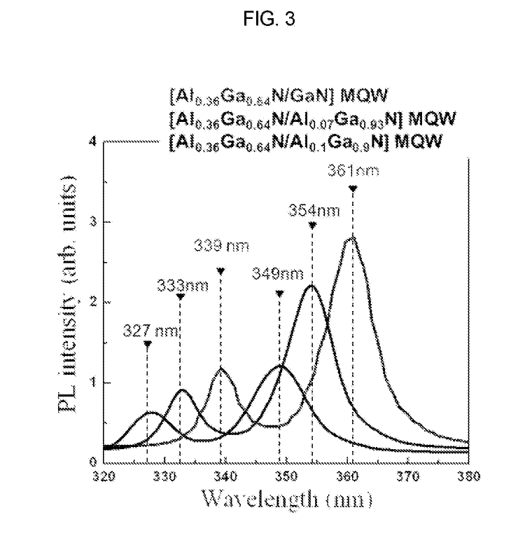

FIG. 3 is a graphic diagram showing the photoluminescence (PL) characteristics of multiple quantum well structures for ultraviolet light-emitting diodes, fabricated by alternately depositing an Al_{0.36}Ga_{0.64}N (3.2 nm thick) barrier portion and an AlₓGa₁₋ₓN (1.2 nm thick, 0≦x₂<0.2) quantum well portion six times. As shown in FIG. 3, as the Al composition ratio (x2) of the Alₓ₂Ga₁₋ₓ₂N quantum well portion increase from 0 to 0.07 and 0.1, the wavelength of light emitted from the multiple quantum well structure decreases.

As described above, in the multiple quantum well structure for the ultraviolet light-emitting diode according to the embodiment of the present invention, the occurrence of dislocation can be effectively inhibited by alternately forming the high-quality barrier layer and the quantum well layer using atomic layer deposition (ALD) which can deposit layers at low temperature.

In addition, the method for fabricating the multiple quantum well structure for the ultraviolet light-emitting diode according to the embodiment of the present invention can easily fabricate the above-described multiple quantum well structure for the ultraviolet light-emitting diode.

Although the preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A multiple quantum well structure for an ultraviolet light-emitting diode, comprising:
an Alₓ₁Ga₁₋ₓ₁N barrier portion comprising an AlN barrier atomic layer and a GaN barrier atomic layer, which are alternately arranged; and
an Alₓ₂Ga₁₋ₓ₂N quantum well portion formed on the Alₓ₁Ga₁₋ₓ₁N barrier portion and comprising an AlN well atomic layer and a GaN well atomic layer, which are alternately arranged, wherein the Al composition ratio (x1) of the Alₓ₁Ga₁₋ₓ₁N barrier portion is 0-0.7, the Al composition ratio (x2) of the Alₓ₂Ga₁₋ₓ₂N quantum well portion is 0-0.7, the Al composition ratio (x1) of the Alₓ₁Ga₁₋ₓ₁N barrier portion is greater than the Al composition ratio (x2) of the Alₓ₂Ga₁₋ₓ₂N quantum well portion, and the Alₓ₁Ga₁₋ₓ₁N barrier portion and the Alₓ₂Ga₁₋ₓ₂N quantum well portion are alternately deposited two or more times.

2. The multiple quantum well structure of claim 1, wherein the Alₓ₁Ga₁₋ₓ₁N barrier portion has a thickness of 3-10 nm.

3. The multiple quantum well structure of claim 1, wherein the Alₓ₁Ga₁₋ₓ₁N barrier portion has a dislocation density of 10⁴-10⁶ ea/cm².

4. The multiple quantum well structure of claim 1, wherein the Alₓ₂Ga₁₋ₓ₂N quantum well portion has a thickness of 1-3 nm.

5. The multiple quantum well structure of claim 1, wherein the Alₓ₂Ga₁₋ₓ₂N quantum well portion has a dislocation density of 10⁴-10⁶ ea/cm².

6. The multiple quantum well structure of claim 1, wherein the number of the Alₓ₂Ga₁₋ₓ₂N quantum well portions is 2-10.

7. A method for fabricating a multiple quantum well structure for an ultraviolet light-emitting diode, the method comprising the steps of:
alternately depositing an AlN barrier atomic layer and a GaN barrier atomic layer to form an Alₓ₁Ga₁₋ₓ₁N barrier portion; and
alternately depositing an AlN well atomic layer and a GaN well atomic layer on the Alₓ₁Ga₁₋ₓ₁N barrier portion to form an Alₓ₂Ga₁₋ₓ₂N quantum well portion, wherein the Alₓ₁Ga₁₋ₓ₁N barrier portion and the Alₓ₂Ga₁₋ₓ₂N quantum well portion are formed such that the Al composition ratio (x1) of the Alₓ₁Ga₁₋ₓ₁N barrier portion is 0-0.7, the Al composition ratio (x2) of the Alₓ₂Ga₁₋ₓ₂N quantum well portion is 0-0.7, the Al composition ratio (x1) of the Alₓ₁Ga₁₋ₓ₁N barrier portion is greater than the Al composition ratio (x2) of the Alₓ₂Ga₁₋ₓ₂N quantum well portion, and the Alₓ₁Ga₁₋ₓ₁N barrier portion and the Alₓ₂Ga₁₋ₓ₂N quantum well portion are alternately deposited two or more times.

8. The method of claim 7, wherein the Alₓ₁Ga₁₋ₓ₁N barrier portion is formed to have a thickness of 3-10 nm.

9. The method of claim 7, wherein the Alₓ₁Ga₁₋ₓ₁N barrier portion has a dislocation density of 10⁴-10⁶ ea/cm².

10. The method of claim 7, wherein the Alₓ₂Ga₁₋ₓ₂N quantum well portion is formed to have a thickness of 1-3 nm.

11. The method of claim 7, wherein the Alₓ₂Ga₁₋ₓ₂N quantum well portion has a dislocation density of 10⁴-10⁶ ea/cm².

12. The method of claim 7, wherein the number of the Alₓ₂Ga₁₋ₓ₂N quantum well portions deposited is 2-10.
